(19) United States
(12) Patent Application Publication
(10) Pub. No.: US 2015/0221570 A1
(43) Pub. Date: Aug. 6, 2015

(54) THIN SANDWICH EMBEDDED PACKAGE

(71) Applicant: Amkor Technology, Inc., Chandler, AZ (US)

(72) Inventors: Christopher J. Berry, Chandler, AZ (US); Robert Lanzone, Chandler, AZ (US); Roger D. St.Amand, Tempe, AZ (US)

(73) Assignee: Amkor Technology, Inc., Chandler, AZ (US)

(21) Appl. No.: 14/172,611

(22) Filed: Feb. 4, 2014

(51) Int. Cl. H01L 23/13; H01L 23/48; H01L 23/00

(52) U.S. Cl. CPC H01L 23/13; H01L 24/81; H01L 23/481; H01L 24/17

(57) ABSTRACT

Methods and systems for a thin sandwich embedded package are disclosed and may include bonding a semiconductor die to a first surface of a substrate, dispensing a bond line on the first surface of the substrate and the die, and bonding an interposer to the substrate and die using the dispensed bond line. The bond line may fill the volume between the interposer and the substrate or may fill the volume between the interposer and the die but not between the interposer and the substrate. A cavity structure may be formed on the interposer and/or substrate, wherein the die may be situated within a cavity formed by the cavity structure when the interposer is bonded to the substrate and die. The cavity structure may comprise solder resist. Contacts may be formed on the cavity structure using low volume pad finish metals to electrically couple the interposer to the substrate.

### FIELD

Certain embodiments of the disclosure relate to semiconductor chip packaging. More specifically, certain embodiments of the disclosure relate to a method and system for a thin sandwich embedded package.

### BACKGROUND

Semiconductor packaging protects integrated circuits, or chips, from physical damage and external stresses. In addition, it can provide a thermal conductance path to efficiently remove heat generated in a chip, and also provide electrical connections to other components such as printed circuit boards, for example. Materials used for semiconductor packaging typically comprises ceramic or plastic, and form-factors have progressed from ceramic flat packs and dual in-line packages to pin grid arrays and leadless chip carrier packages, among others.

Further limitations and disadvantages of conventional and traditional approaches will become apparent to one of skill in the art, through comparison of such systems with the present disclosure as set forth in the remainder of the present application with reference to the drawings.

### BRIEF DESCRIPTION OF SEVERAL VIEWS OF THE DRAWINGS

FIG. 1 is a schematic illustrating a thin sandwich embedded package, in accordance with an example embodiment of the disclosure.

FIG. 2 is a schematic illustrating a thin sandwich embedded package with bond material filled gap, in accordance with an example embodiment of the disclosure.

FIG. 3 is a schematic illustrating a thin sandwich embedded package with an interposer cavity structure, in accordance with an example embodiment of the disclosure

FIG. 4 is a schematic illustrating a thin sandwich embedded package with a substrate cavity structure, in accordance with an example embodiment of the disclosure.

FIG. 5 is a schematic illustrating a thin sandwich embedded package with substrate and interposer cavity structure, in accordance with an example embodiment of the disclosure.

FIG. 6 illustrates example steps in forming a thin sandwich embedded package, in accordance with an example embodiment of the disclosure.

### DETAILED DESCRIPTION

Certain aspects of the disclosure may be found in a thin sandwich embedded package. Example aspects of the disclosure may, for example, comprise bonding a semiconductor die to a first surface of a substrate, dispensing a bond line on the first surface of the substrate and the semiconductor die, and bonding an interposer to the substrate and semiconductor die using the dispensed bond line. The bond line may fill the volume between the interposer and the substrate or may fill the volume between the interposer and the semiconductor die but not between the interposer and the substrate. A cavity structure may be formed on one or both of the interposer and substrate, and the semiconductor die may be situated within a cavity formed by the cavity structure when the interposer is bonded to the substrate and semiconductor die. The cavity structure may comprise solder resist. Contacts may be formed on the cavity structure using low volume pad finish metals to electrically couple the interposer to the substrate. Metal contacts on the interposer may be bonded to metal contacts on the substrate. The metal contacts may comprise solder balls and/or copper pillars/posts. Metal contacts may be formed on a second surface of the substrate. A subset of metal contacts on the first surface of the substrate may be electrically coupled to a subset of the metal contacts on the second surface of the substrate utilizing vias within the structure.

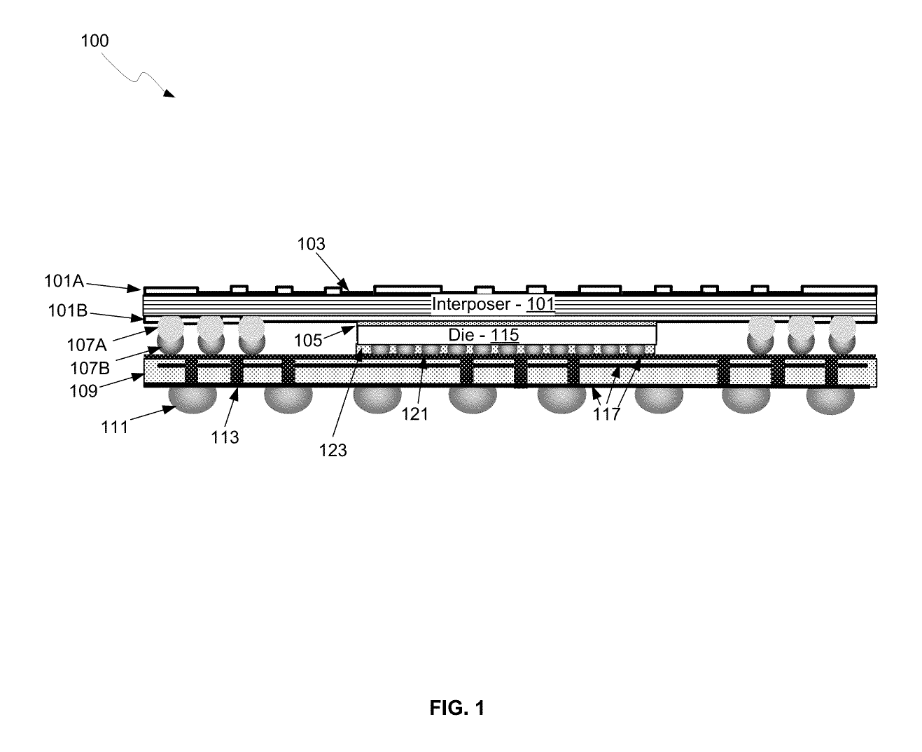

FIG. 1 is a schematic illustrating a thin sandwich embedded package, in accordance with an example embodiment of the disclosure. Referring to FIG. 1, there is shown a package 100 comprising an interposer 101, a semiconductor die 115, and a substrate 109. The semiconductor die 115 and the substrate 109 form a base package.

The semiconductor die 115 may comprise an integrated circuit die that has been separated from a semiconductor wafer and may have contacts 121 (e.g., conductive bumps or other conductive structures) formed on one surface to provide electrical connection to the substrate 109. The semiconductor die 115 may comprise electrical circuitry such as digital signal processors (DSPs), microprocessors, network processors, power management units, audio processors, RF circuitry, wireless baseband system-on-chip (SoC) processors, sensors, and application specific integrated circuits, for example. An underfill material 123 may fill the gap between the semiconductor die 115 and the substrate 109 for added mechanical rigidity and to protect the contacts 121 that electrically couple the die 115 to the substrate 109. Accordingly, metal pads on the substrate may receive the contacts 121, which may comprise solder balls, for example.

The interposer 101 may comprise a multi-layer structure with metal, semiconductor, and dielectric layers that provide electrical interconnectivity and isolation, respectively, for devices and structures bonded to the interposer 101. The metal pads 103 on the interposer 101 may comprise contact pads for receiving conductive bumps or other contact types from subsequently bonded semiconductor die or other devices. In addition, the interposer 101 may comprise solder resist layers 101A and 101B that cover the top and bottom surfaces of the interposer 101 with openings wherever contact is to be made.

The substrate, or base laminate, 109 may comprise metal layers, such as the metal layers 117, for electrical connectivity laterally in the substrate 109, dielectric layers for electrical isolation between the metal layers 117, and vias 113 may comprise core, blind, or through vias, for example and may provide electrical connectivity through the substrate 109. In an example scenario, the vias 113 may provide electrical connectivity from the substrate top surface to the solder balls 111, which may provide electrical and mechanical connectivity of the package 100 to a printed circuit board, for example. The vias 113 may be formed by drilling through the laminate substrate and plating with metal to provide an electrical interconnect between top and bottom surfaces. Vias may also be formed by laser drilling and subsequent filling; both of these techniques being such that are practiced in printed wiring board manufacturing presently. While the interposer 101 and substrate 109 as shown may comprise organic laminate structures, they are not so limited, and may comprise any multi-layer structure or glass, for example.

The package 100 may also comprise metal contacts 107A and 107B formed on the interposer 101 and the substrate 109, respectively, for providing electrical connectivity between the interposer 101 and the substrate 109. The metal contacts 107B may be formed on metal pads, not shown, but similar to the metal pads 103, on the substrate 109 and the metal contacts 107A may be formed on the interposer 101. In this manner, the interposer 101 and the substrate 109 may be electrically coupled by bonding the metal contacts 107A to the metal contacts 1078. The metal contacts 107A and 107B may comprise solder balls or copper posts, for example, but are not limited to such contacts, and may comprise solder. finish on a copper pad or any other configuration that accomplishes an electrical connection including a conductive polymer, or other metal systems.

The bond line 105 may comprise an adhesive layer formed on the semiconductor die 115 and/or the interposer 101 for bonding the interposer 101 to the semiconductor die and the substrate 109. The bond line 105 may, for example, comprise classes of materials known as: a) non-conductive pastes (NCP), and b) non-conductive films (NCF), and c) epoxy fluxes (EF). NCPs may comprise glass filled epoxy where glass powder mixed in with epoxy may help to manage the expansivity of the material. Epoxies may have high expansivity whereas glass may have low expansivity, so the addition of glass may reduce the expansivity of the mixed material. The epoxies may be selected so that they also permit solder wetting when joining the interposer and may have sufficiently high Tg so as to perform well in the structure regarding thermo-mechanical reliability.

Epoxy fluxes may not comprise added glass but perform the same or similar function. The addition of fluxing agents to these materials may aid in the solder to solder wetting when joining the interposer to the base package. Therefore, the bond line 105 may comprise an adhesive material in the presence of which solder wetting is possible. Since the bond line 105 may comprise a full body bond line, the adhesive bond line encapsulates interface joints and intimately bonds the interposer 101 to the base package element comprising the substrate 109 and the die 115. As will be discussed in more detail below, the bond line 105 may also (or alternatively) extend between the interposer 101 and the substrate 109.

In an example scenario, the semiconductor die 115 may comprise a processor, and one or more memory die may be bonded to the metal pads 103 on the interposer 101. In this scenario, the interposer 101, the metal contacts 107A and 107B, and the substrate 109 may provide electrical connectivity between bonded memory die and the semiconductor die 115 as well as to the motherboard on which the TSEP will eventually be mounted.

The package 100 may comprise a thin sandwich embedded package (TSEP) where an interposer 101 may be bonded to the semiconductor die 115 utilizing the bond line 105 without mold material in the volume between the substrate 109 and the interposer 101. Compared to other approaches, TSEP may be a truly unit based sandwiching approach which may be a major advantage in terms of yield and ease of manufacture and may not require conductor delineation or forming after sandwiching the die, which may be a source of yield loss. In addition, TSEP requires neither molding nor any rigid standoff of the substrate 109 to interposer 101 interconnection as do other types of packages that are molded after interposers are attached to substrates [e.g. MCeP.

In another example scenario, the bond line 105 may be pre-applied to the interposer 101, and may only extend beyond the edges of the die and not extend to the edges of the package. Alternatively, the bond line 105 may extend beyond the edges of the die 115 flowing around it but not extend to the contacts 107A and 107B.

The process flow described above for fabricating the package 100 illustrates a ‘unit-to-unit’ sandwich process. However, the structures may also be produced with the base package, comprising the die and substrate, being in strip format and with the interposers being in single unit form (or matrix of units form) at the time of the sandwich operation. This flexibility demonstrates the advantages of the process described. More specifically and for example, CIS is a full panel or strip-based process only and MCeP is exclusively an array-to-strip process. Both of these examples, therefore, cannot mathematically achieve the same yields as the TSEP process described herein.

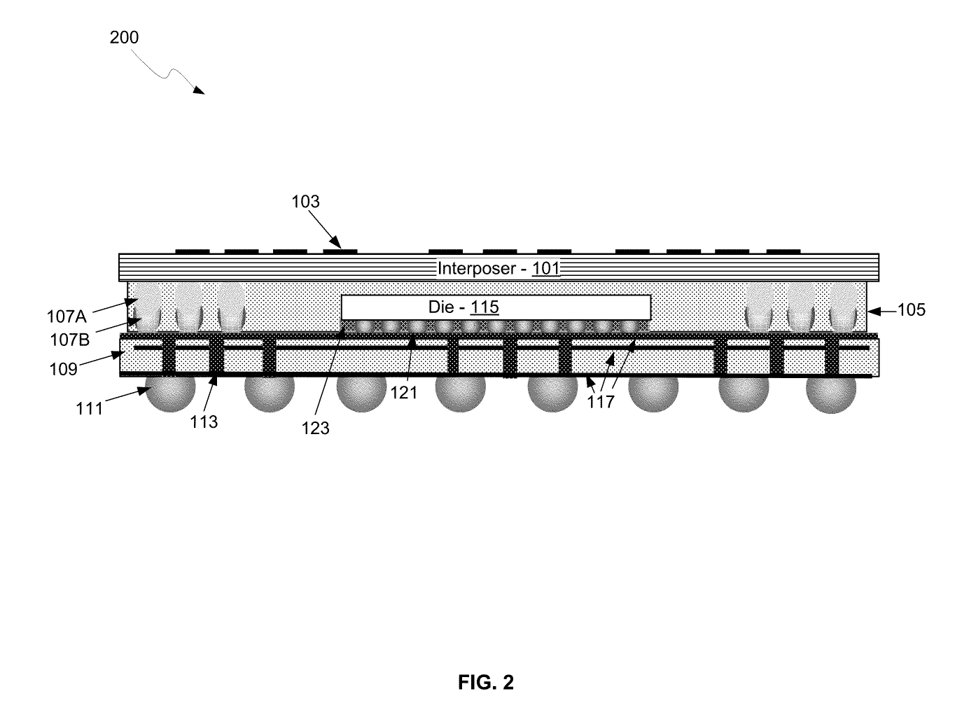

FIG. 2 is a schematic illustrating a thin sandwich embedded package with bond material filled gap, in accordance with an example embodiment of the disclosure. Referring to FIG. 2, there is shown a package 200 with similar elements to the package 100, such as the interposer 101, substrate 109, semiconductor die 115, and metal contacts 107A and 107B.

There is also shown bond line 105 that may bond the interposer 101 to the substrate 109 and the die 115. In an example scenario, the bond line 105 may fill the gap between the interposer 101 and substrate 109, as opposed to only being between the semiconductor die 115 and the interposer 101 as shown in FIG. 1. The bond line 105 may encapsulate the semiconductor die 115, the underfill 123 (if any), and the contacts 107A and 107B, providing both mechanical support and protection from environmental factors.

The packages 100 and 200 may, for example, be formed with contacts being solder to solder, solder to copper in either orientation, solder capped copper from both sides, or any combination thereof.

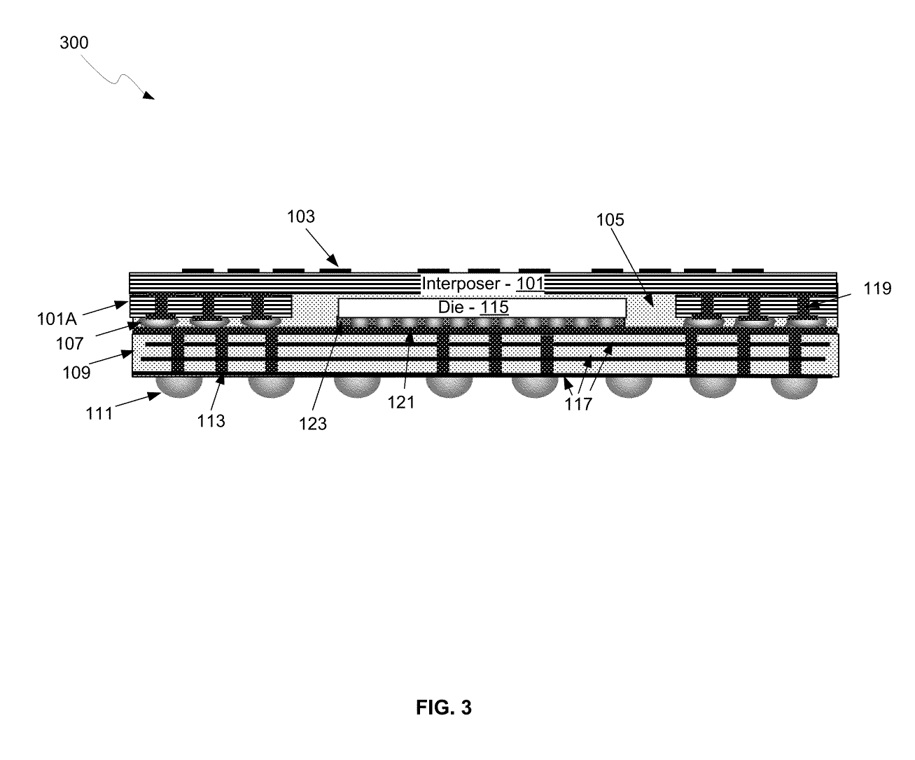

FIG. 3 is a schematic illustrating a thin sandwich embedded package with an interposer cavity structure, in accordance with an example embodiment of the disclosure. Referring to FIG. 3, there is shown a package 300 with similar elements to the packages 100 and 200, such as the interposer 101, substrate 109, and semiconductor die 115.

There is also shown bond line 105 that may bond the interposer 101 to the substrate 109 and the die 115 and fill the volume between these structures without the need for mold material. Additionally, a cavity structure 101A may be formed on the interposer 101. The cavity structure 101A may comprise a laminate extension of the laminate structure of the interposer 101 that may extend down from the surface of the interposer 101 to surround the semiconductor die 115. The cavity structure 101A may comprise vias 119, which may comprise blind or through vias, for example, for providing electrical connectivity between the interposer 101 and the substrate 109, which also provides connectivity to the semiconductor die 115. In this manner, a high-density memory interface (MIF) to one or more die bonded to the contact pads 103 may be provided in a thin sandwiched embedded package. The package 300 might not, for example, have any mold material between the laminate structures, the interposer 101 and the substrate 109, which may simplify the manufacturing process due to the elimination of mold compound from the bill of materials, and the elimination of related molding process equipment.

The package 300 illustrates connections made with low volume pad finish metals which may comprise electrically conductive materials that may be joined upon the bonding of the interposer to the base package, such as a solder material, for example. The contacts 107 are low volume in that the pad finish would simply need to protrude slightly beyond the bottom side of the interposer cavity structure 101A and the top side of the base package 109. Solder resist is basically the surface material of the interposer and base package substrate and may comprise the outer layers [top and bottom] of the laminate substrates, the base package or substrate 109 and the interposer 101.

In an example scenario, the contacts 107 may be formed with solder to solder, solder to copper in either orientation, solder capped copper from both sides, or any combination thereof, but in a much smaller volume than for example in a configuration without a cavity structure, e.g., the so-called “solder on pad” finish. This lower volume joint feature is a direct result of the cavity structure 101A itself in that the cavity may provide much of the vertical connection distance between the interposer 101 and substrate 109, therefore enabling the use of a much lower volume of joint material at the connection interface.

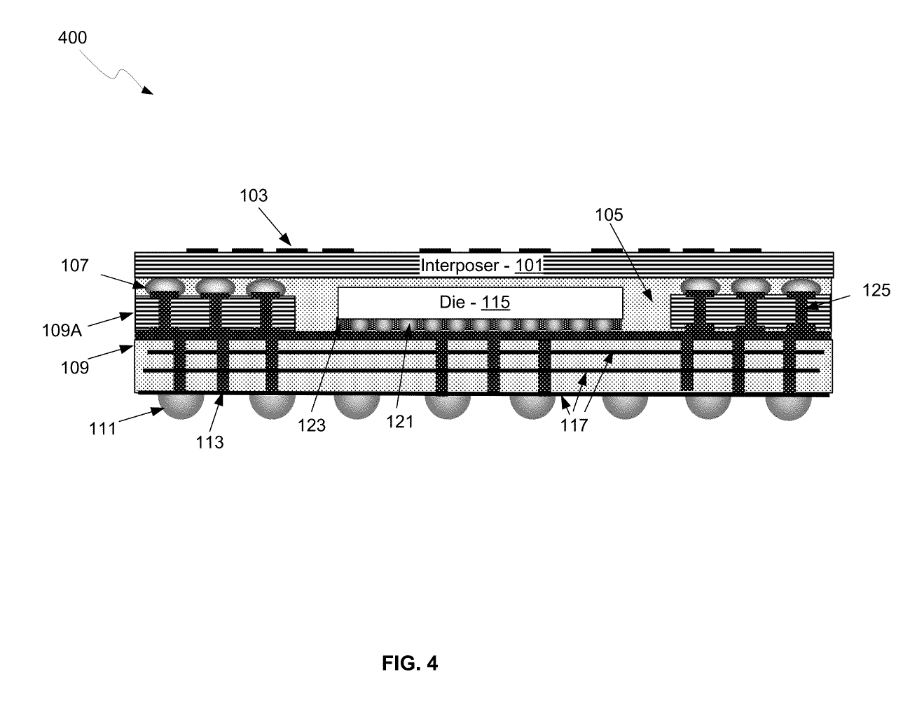

FIG. 4 is a schematic illustrating a thin sandwich embedded package with a substrate cavity structure, in accordance with an example embodiment of the disclosure. Referring to FIG. 4, there is shown a package 400 with similar elements to the packages 100, 200, and 300, such as the interposer 101, package 109, and semiconductor die 115.

There is also shown bond line 105 that may bond the interposer 101 to the substrate 109 and the die 115 and fill the volume between these structures without the need for mold material. Additionally, a cavity structure 109A may be formed on the substrate 109. The cavity structure 109A may comprise a laminate extension of the laminate structure of the substrate 109 that may extend up from the surface of the substrate 109 to surround the semiconductor die 115. The cavity structure 109A may comprise vias 125, which may or may not be similar to the vias 113, for providing electrical connectivity between the substrate 109 and the interposer 101, where the substrate 109 also provides connectivity to the semiconductor die 115. In this manner, a high-density memory interface (MIF) to one or more die bonded to the contact pads 103 may be provided in a thin sandwiched embedded package. The package 400 might not, for example, have any mold material between the laminate structures, the interposer 101 and the substrate 109, which may simplify the manufacturing process.

The package 400 illustrates connections made with low volume pad finish metals which may comprise electrically conductive materials that may be joined upon the bonding of the interposer to the base package, such as a solder material, for example. The contacts 107 are low volume in that the pad finish would simply need to protrude slightly beyond the top of the substrate cavity structure 109A and below the bottom of the interposer 101. In another example scenario, each of the contacts 107 may comprise a pair of contacts formed on each structure, as shown by the contacts 107A and 107B in FIG. 1, for example. A solder resist material may comprise the surface of the interposer 101 and base package substrate 109. Solder resist may comprise the outer layers [top and bottom] of the laminate substrates, the base package or substrate 109 and the interposer 101.

In an example scenario, the contacts 107 may be formed with solder to solder, solder to copper in either orientation, solder capped copper from both sides, or any combination thereof, but in a much smaller volume than for example in a configuration without a cavity structure, as shown in FIGS. 1 and 2, due to the cavity structure 109A, and as discussed with respect to FIG. 3.

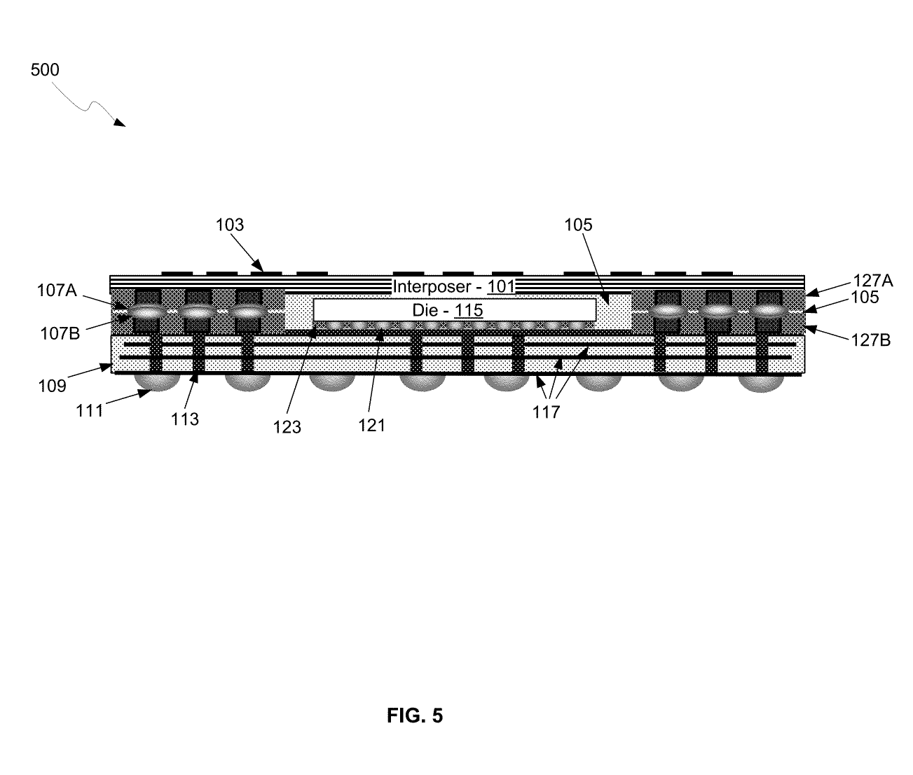

FIG. 5 is a schematic illustrating a thin sandwich embedded package with substrate and interposer cavity structure, in accordance with an example embodiment of the disclosure. Referring to FIG. 5, there is shown a package 500 with similar elements to the packages 100, 200, 300, and 400, such as the interposer 101, substrate 109, and semiconductor die 115.

There is also shown a bond line 105 that may bond the interposer 101 to the substrate 109 and the die 115 and fill the volume between these structures without the need for mold material. Additionally, solder resist cavity structures 127A and 127B may be formed on the interposer 101 and substrate 109, respectively and therefore eliminating the need for conventional cavity features which typically involve added dielectric and metal layers in the laminate fabrication process. Alternatively, cavity structures 127A and 127B may be formed as illustrated in FIGS. 3 and 4 and discussed previously.

The solder resist cavity structures 127A and 127B may comprise extensions of the structure of the interposer 101 and substrate 109 that may extend down and/or up from these structures to surround the semiconductor die 115. The solder resist cavity structures 127A and 127B may comprise metal contacts 107A and 107B, respectively, for providing electrical connectivity between the interposer 101 and the substrate 109 (e.g., through conductive paths extending through the solder resist cavity structures 127A and 127B), which also provides connectivity to the semiconductor die 115. In this manner, a high-density memory interface (MIF) to one or more die bonded to the contact pads 103 may be provided in a thin sandwiched embedded package. The package 500 might not, for example, have any mold material between the laminate structures, the interposer 101 and the substrate 109, which may simplify the manufacturing process, and eliminate materials from the BOM (Bill of Materials).

The package 500 illustrates connections made with low volume pad finish metals, which may comprise electrically conductive materials that may be joined upon the bonding of the interposer to the base package, such as a solder material, for example. The contacts 107A and 107B are low volume in that the pad finish would simply need to protrude slightly beyond the bottom and above the top of the solder resist cavity structures 127A and 127B, respectively.

In an example scenario, the contacts 107A and 107B may be formed with solder to solder, solder to copper in either orientation, solder capped copper from both sides, or any combination thereof, but in a much smaller volume than for example in a configuration without a cavity structure, such as shown in FIGS. 1 and 2, due to the solder resist cavity structures 127A and 127B, and as discussed with respect to FIG. 3.

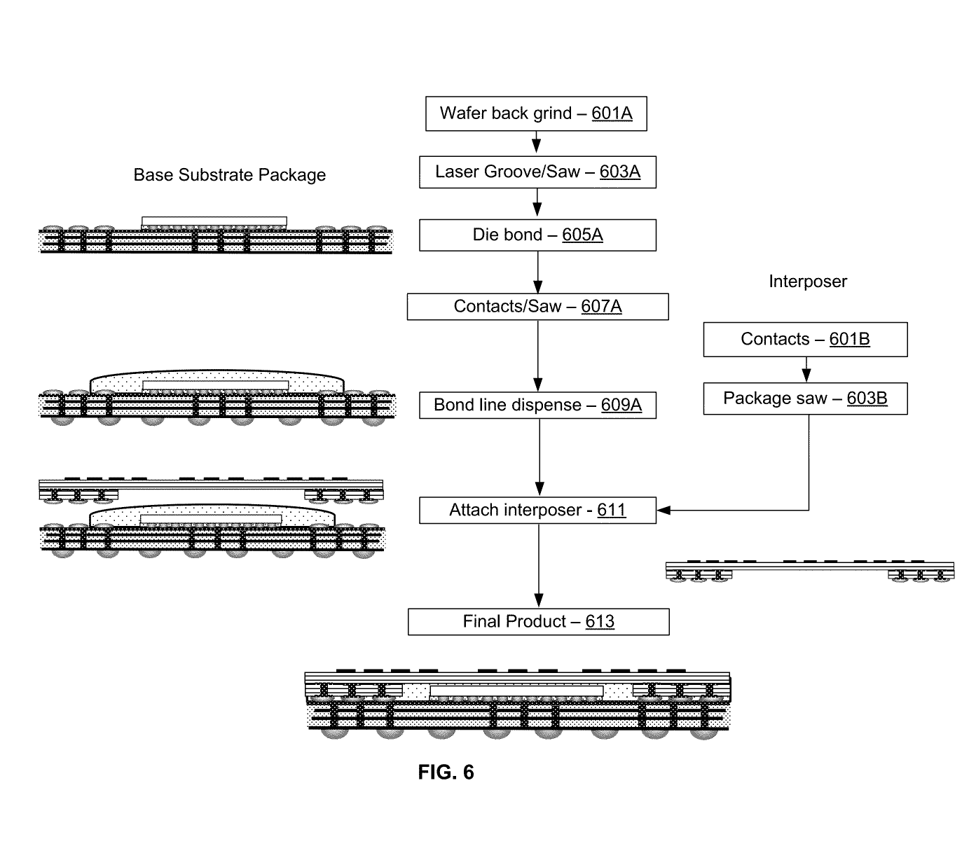

FIG. 6 illustrates example steps in forming a thin sandwich embedded package, in accordance with an example embodiment of the disclosure. Referring to FIG. 6, there is shown parallel process paths, one for the interposer and the other for the base substrate package. The processes may be performed in parallel, although not necessarily, and non-limiting example resulting structures are shown next to the process steps in FIG. 6.

Considering the base package process first, a wafer from which the semiconductor die may be separated may receive a back grind in step 601A to thin the die to a desired thickness. In step 603A, the wafer may be cut utilizing a laser or saw, for example, resulting in individual semiconductor die.

In step 605A, one or more of the diced semiconductor die may be bonded to the base substrate utilizing a thermal compression process with non-conductive paste, for example, although other bonding techniques, such as mass reflow, may be utilized. Solder balls or conductive bumps (or other contact structures) on the die may be bonded to contact pads on the substrate. Additionally, a capillary underfill may be applied between the die and the substrate after contact bonding.

In step 607A, if the base substrate is in strip form, it may be sawn into individual substrate/die units, followed by step 609A, where bond material may be dispensed onto the substrate and bonded die. The bond material may be applied with enough material to fill the region between the interposer and substrate, as shown in FIGS. 2-5, or may only fill the region between the die and interposer, as shown in FIG. 1, or may fill the region between the die and interposer and a portion of the region between the interposer and the substrate. In an alternative step 609A, the bond line may be dispensed on the interposer, for example with enough bonding material to fill the region(s) as discussed above.

Next, considering the interposer fabrication steps, an interposer laminate strip or single interposer unit, may be processed, in that metal contacts, such as solder balls, solder bumps, or copper posts, may be formed on the bottom side of the interposer strip or unit in step 601B. Although solder balls are shown, other contact types may be utilized, such as tinning with printed paste, for example. The metal contacts may be placed for bonding to the metal contacts formed on the base substrate package. In addition metal pads may be formed on the top surface of the interposer for receiving semiconductor die or other devices. In another example scenario, the interposer may be received with metal pads already formed on the top surface.

If in strip format, the interposer laminate may then be sawn, diced, or cut into individual interposer substrates in step 603B. In step 613, the interposer may be bonded to the base substrate package using the bond line, with the contacts formed on the interposer coinciding with contacts formed on the base substrate package or cavity structure, resulting in the final package in step 613.

The process steps described in FIG. 6 illustrate a “unit-to-unit” sandwich process. The structures may also be produced with the base package in strip format and the interposers in single unit form and/or in unit matrix form at the time of the sandwich operation.

In an embodiment of the disclosure, a device is disclosed for a thin sandwich embedded package. In this regard, aspects of the disclosure may comprise bonding a semiconductor die to a first surface of a substrate, dispensing a bond line on the first surface of the substrate and the semiconductor die, and bonding an interposer to the substrate and semiconductor die using the dispensed bond line. The bond line may fill the volume between the interposer and the substrate or may fill the volume between the interposer and the semiconductor die but not between the interposer and the substrate.

A cavity structure may be formed on one or both of the interposer and substrate, and the semiconductor die may be situated within a cavity formed by the cavity structure when the interposer is bonded to the substrate and semiconductor die. The cavity structure may comprise solder resist and/or laminate structure extensions. Contacts may be formed on the cavity structure using low volume pad finish metals to electrically couple the interposer to the substrate.

Metal contacts on the interposer may be bonded to metal contacts on the substrate. The metal contacts may comprise solder balls, copper pillars, and/or copper pads. Metal contacts may be formed on a second surface of the substrate. A subset of metal contacts on the first surface of the substrate may be electrically coupled to a subset of the metal contacts on the second surface of the substrate utilizing vias through the structure.

While the disclosure has been described with reference to certain embodiments, it will be understood by those skilled in the art that various changes may be made and equivalents may be substituted without departing from the scope of the present disclosure. In addition, many modifications may be made to adapt a particular situation or material to the teachings of the present disclosure without departing from its scope. Therefore, it is intended that the present disclosure not be limited to the particular embodiments disclosed, but that the present disclosure will include all embodiments falling within the scope of the appended claims.

What is claimed is:

1. (canceled)

2. (canceled)

3. (canceled)

4. (canceled)

5. (canceled)

6. (canceled)

7. (canceled)

8. (canceled)

9. (canceled)

10. (canceled)

11. A semiconductor device comprising:
a semiconductor die bonded to a first surface of a substrate;
a bond line on the first surface of the substrate and the semiconductor die; and
an interposer bonded to the substrate and semiconductor die using the bond line.

12. The semiconductor device according to claim 11, wherein the bond line fills the volume between the interposer and the substrate.

13. The semiconductor device according to claim 11, wherein the bond line fills the volume between the interposer and the semiconductor die but not between the interposer and the substrate.

14. The semiconductor device according to claim 11, wherein a cavity structure is formed on one or both of the interposer and substrate, and wherein the semiconductor die is situated within a cavity formed by the cavity structure when the interposer is bonded to the substrate and semiconductor die.

15. The semiconductor device according to claim 11, wherein the cavity structure comprises solder resist.

16. The semiconductor device according to claim 11, wherein contacts formed on the cavity structure comprise low volume pad finish metals that electrically couple the interposer to the substrate.

17. The semiconductor device according to claim 11, wherein metal contacts on the interposer are bonded to metal contacts on the substrate.

18. The semiconductor device according to claim 17, wherein the metal contacts comprise solder balls and/or copper pillars.

19. The semiconductor device according to claim 11, wherein metal contacts formed on a second surface of the substrate are electrically coupled to metal contacts on the first surface of the substrate utilizing vias.

20. (canceled)

21. A semiconductor device comprising:
a semiconductor die bonded to a first surface of a first laminate structure;
a bond line on the first surface of the first laminate structure and the semiconductor die;
a second laminate structure bonded to the first laminate structure and semiconductor die using the bond line; and
a cavity structure between the first and second laminate structures, wherein the bond line and the semiconductor die are within the cavity structure.

22. The semiconductor device according to claim 21, wherein the bond line fills the volume between the first and second laminate structures.

23. The semiconductor device according to claim 21, wherein the bond line fills the volume between the second laminate structure and the semiconductor die but not between the first and second laminate structures.

24. The semiconductor device according to claim 21, wherein the cavity structure comprises solder resist.

25. The semiconductor device according to claim 21, wherein contacts formed on the cavity structure comprise low volume pad finish metals that electrically couple the second laminate structure to the first laminate structure.

26. The semiconductor device according to claim 21, wherein metal contacts on the second laminate structure are bonded to metal contacts on the first laminate structure.

27. The semiconductor device according to claim 26, wherein the metal contacts comprise solder balls.

28. The semiconductor device according to claim 26, wherein the metal contacts comprise copper pillars.

29. The semiconductor device according to claim 21, wherein metal contacts formed on a second surface of the first laminate structure are electrically coupled to metal contacts on the first surface of the first laminate structures utilizing vias.

30. The semiconductor device according to claim 29, wherein solder balls are formed on the metal contacts formed on the second surface of the first laminate structure.

31. The semiconductor device according to claim 21, wherein the cavity structure comprises solder resist material formed on both the first laminate structure and the second laminate structure
